(19) United States
(12) Patent Application Publication
(10) Pub. No.: US 2015/0221792 A1
(43) Pub. Date: Aug. 6, 2015

(54) Self Aligned Contacts for Solar Cells

(71) Applicant: Solexel, Inc., Milpitas, CA (US)

(72) Inventors: Anand Deshpande, Cupertino, CA (US); Pawan Kapur, Burlingame, CA (US); Mehrdad M. Moslehi, Los Altos, CA (US); Virendra V. Rana, Los Gatos, CA (US); Sean M. Seutter, San Jose, CA (US)

(21) Appl. No.: 14/582,177

(22) Filed: Dec. 23, 2014

Related U.S. Application Data
(60) Provisional application No. 61/920,271, filed on Dec. 23, 2013.
(60) Provisional application No. 61/945,116, filed on Feb. 26, 2014.

(51) Int. Cl. H01L 31/0224; H01L 31/068

(52) U.S. Cl. CPC H01L 31/022441; H01L 31/0682

(57) ABSTRACT

Fabrication methods for forming self aligned contacts for back contact solar cells are provided.

### CROSS-REFERENCE TO RELATED APPLICATIONS

This application claims the benefit of U.S. provisional patent applications 61/920,271 filed Dec. 23, 2013 and 61/954,116 filed Feb. 26, 2014, all of which are hereby incorporated by reference in their entirety.

### FIELD OF THE INVENTION

The present disclosure relates in general to the fields of photovoltaic (PV) solar cells, and more particularly to self aligned contacts for solar cells.

### BACKGROUND

As photovoltaic solar cell technology is adopted as an energy generation solution on an increasingly widespread scale, fabrication and efficiency improvements relating to solar cell efficiency, metallization, material consumption, and fabrication are required. Manufacturing cost and conversion efficiency factors are driving solar cell absorbers ever thinner in thickness and larger in area, thus, increasing the mechanical fragility, efficiency, and complicating processing and handling of these thin absorber based solar cells—fragility effects increased particularly with respect to crystalline silicon absorbers.

Generally, solar cell contact structure includes conductive metallization on base and emitter diffusion areas—for example aluminum metallization connecting silicon in base and emitter contact areas through relatively heavy phosphorous and boron areas, respectively.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIGS. 1A through 1D are cross-sectional diagrams of solar cells with a self aligned contact structure;

FIGS. 2A through 2E are cross-sectional diagrams of solar cells at various steps during the fabrication of a abutted junction interdigitated back contact solar cell having self aligned contacts;

FIGS. 3A through 3G are cross-sectional diagrams of solar cells at various steps during the fabrication of a non abutted junction interdigitated back contact solar cell having self aligned contacts; and

FIGS. 4A through 4E are cross-sectional diagrams of solar cells at various steps during the fabrication of a non abutted junction interdigitated back contact solar cell having self aligned contacts.

### BRIEF SUMMARY

Therefore, a need has arisen for fabrication methods for back contact solar cells. In accordance with the disclosed subject matter, methods for the fabrication of back contact solar cells are provided. These innovations substantially reduce or eliminate disadvantages and problems associated with previously developed back contact solar cell fabrication methods.

Related patent applications having partially common inventorship and providing structure and fabrication details in addition to those described herein include U.S. patent application Ser. No. 14/179,526 filed Feb. 2, 2014, U.S. patent application Ser. No. 14/072,759 filed Nov. 5, 2013 (Published as U.S. Pub. 20140326295 on Nov. 6, 2014), U.S. patent Ser. No. 13/869,928 filed Apr. 24, 2013 (Published as U.S. Pub. 20130228221 on Sep. 5, 2013), U.S. patent application Ser. No. 14/493,341 filed Sep. 22, 2014, and U.S. patent application Ser. No. 14/493,335 filed Sep. 22, 2014, all of which are hereby incorporated by reference in their entirety.

According to one aspect of the disclosed subject matter, self aligned contacts for a back contact back junction solar cell are provided. The solar cell comprises a semiconductor layer having a light receiving frontside and a backside opposite the frontside and attached to an electrically insulating backplane. A first metal layer having base and emitter electrodes self aligned to base and emitter regions is positioned on the semiconductor layer backside. A patterned second metal layer providing cell interconnection and connected to the first metal layer by via plugs is positioned on the backplane.

These and other advantages of the disclosed subject matter, as well as additional novel features, will be apparent from the description provided herein. The intent of this summary is not to be a comprehensive description of the subject matter, but rather to provide a short overview of some of the subject matter's functionality. Other systems, methods, features and advantages here provided will become apparent to one with skill in the art upon examination of the following FIGURES and detailed description. It is intended that all such additional systems, methods, features and advantages included within this description be within the scope of the claims.

The disclosed subject matter provides structures and methods for making self aligned contacts for back contact back junction solar cells. Specifically, the disclosed subject matter and corresponding figures provide low-damage, high-efficiency, and low-cost process flows for the formation of thin silicon solar cells using self aligned contacts for back contact back junction (e.g., interdigitated back contact IBC) solar cells. The novel self aligned contact structures described may achieve higher solar cell conversion efficiency. Additionally, solar cell fabrication methods having minimal or reduced process steps for the formation of solar cell structures with self aligned contacts are described.

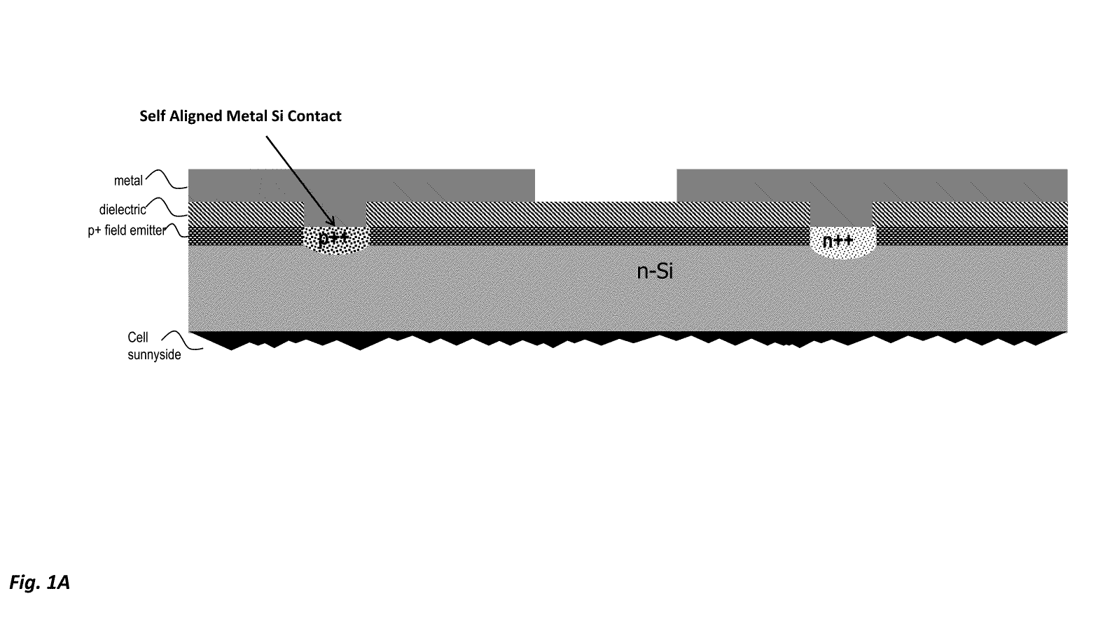

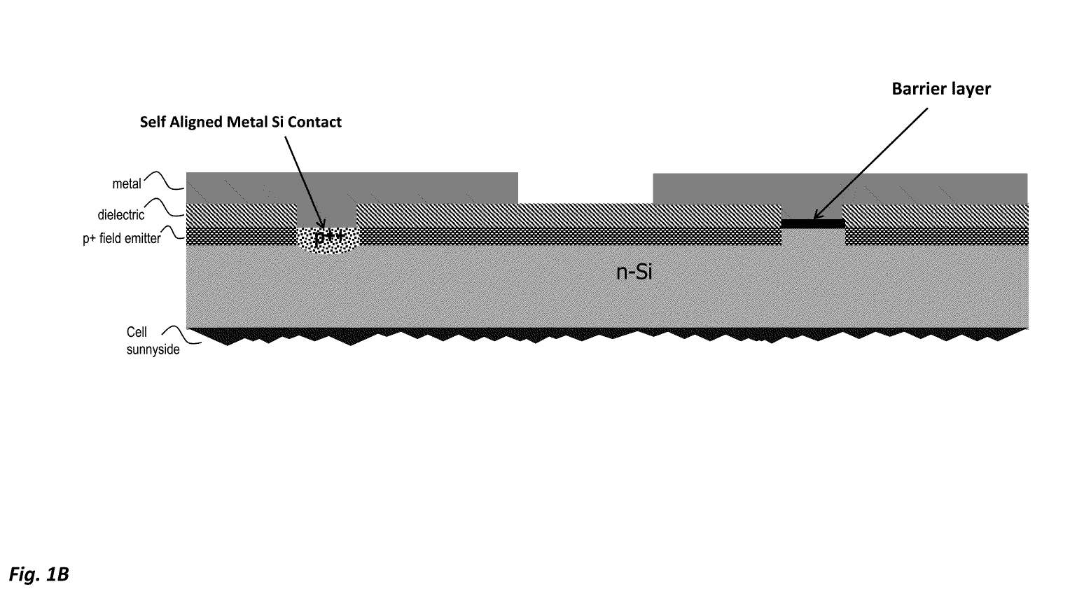

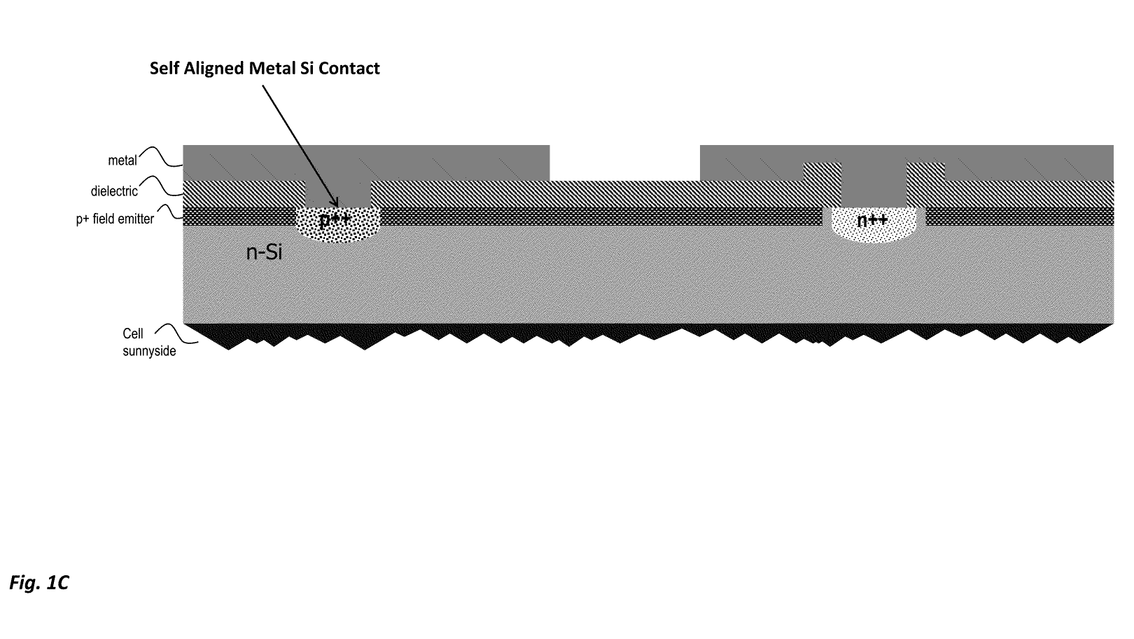

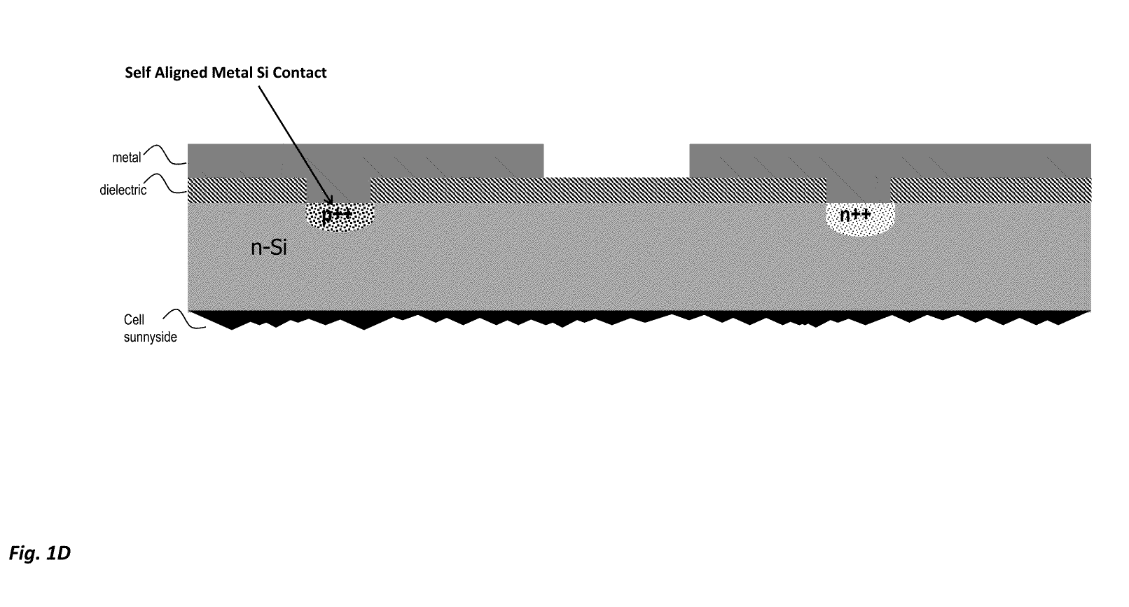

The term self aligned describes cell structure such that the heavy doping of n+ and p+ areas under the base and emitter metal contacts are self-aligned with respect to the contact openings—such as that shown in FIGS. 1A through 1D. FIG. 1A is a cross-sectional diagram of a selective emitter solar cell with a self aligned contact structure having a dopant diffusion region with higher doping levels (e.g., greater than 1E18 cm-3) just below the metal to silicon absorber contact. Self aligned contact structures may provide higher solar cell efficiency by having heavily doped regions (n and p type) in silicon for improved metal/Si contact resistance and lower surface recombination velocity at metal/Si contact and by minimizing heavy doping areas (e.g., doping greater than 1E18 cm-2) in the solar cell thus reducing the overall saturation current density. Alternatively, self aligned contact structure disclosed herein may also be formed by using hetero/tunneling contacts through a barrier layer in between metal and Si—such as that shown in FIG. 1B. FIG. 1B is a cross-sectional diagram of a solar cell with a self aligned contact structure formed using hetero/tunneling contacts through a barrier layer in between metal and Si.

An advantage of a self aligned structure is that heavy doping areas are limited to only under the contact where they are needed. If the contact open needs to be aligned to the heavy doping with non-self aligned contact structures, the heavy diffusions need to be much wider than the contact open to accommodate for alignment tolerances. As compared to non-self aligned contact structures, the self aligned contact structures provided may have higher efficiency because of two distinct reasons. First, heavy dopings may be deleterious when used under passivation—in other words heavy dopings are more and in some instances only useful when used under poor passivation such as metal. Thus, a self-aligned structure eliminates the areas of heavy doping under high quality passivation. Second, for a non-self aligned structure two openings need to be made: first for doping and second for contact open. If these openings are made using methods which are prone to creating damage in silicon (e.g., in some instances laser processing) a self-aligned structure removes the outer nesting opening and minimizes and in some instances eliminates laser damage from this step. Further, in addition to efficiency advantages, the self-aligned structure may require less process steps and thus reduce cell cost.

Table 1 below shows a front-end process flow for the formation of a selective emitter solar cell having self aligned contacts and a field emitter—such as that shown in FIG. 1A—using a dopant paste step.

TABLE 1
Selective emitter solar cell having self aligned
contacts with dopant paste and a field emitter.

| | |
|---|---|
| 1 | Saw Damage Removal |
| 2 | APCVD Boron Doped Al2O3 + Undoped SiO2 |
| 3 | Laser ablation (ns UV and/or ps UV) |
| 4 | Dopant Paste (Phos Paste Print − Dry + Boron Paste Print Dry) |
| 5 | Diffusion Anneal |
| 6 | Wet Etch (eg. Dilue HF, SC1 or dilute KOH based etc) |

Table 1 shows a process flow where self-aligned contact is used for making high efficiency back contact back junction solar cell. Shown, Step 1 is a saw damage removal step to remove damage from a wafer (e.g., a CZ wafer); however, the flows provided are equally applicable to an epitaxially formed silicon substrate processed while on template in which case Step 1 Saw Damage Removal is replace with a porous silicon and epitaxial silicon deposition step as described in detail herein. Thus, in epitaxial embodiments, the front-end processing described occurs on the exposed surface of the template attached epitaxial substrate after which the epitaxial substrate may be released (e.g., mechanical or wet etch release) from the template in back end processing. Importantly, the exemplary process flows provided are described in the context of fabrication high efficiency back contact back junction solar cells for descriptive purposes and one skilled in the art may combine, add or remove, alter, or move within an overall process flow the various processing steps disclosed. In other words, elements from each of the process flows described in the table provided herein may be combined together or with other known solar cell manufacturing methods. For example, with reference to Table 1: the laser contact open shown in Step 3 in can be separated in two steps (for example as shown in Table 2) to form self aligned contacts only for base and emitter contacts separately; the dopant paste printing step shown in Step 4 may have additional third print of undoped paste on top of already printed dopant pastes (for example as shown in FIG. 8). Further, the wet etch step shown in Step 6 of Table 1 and which removes annealed dopant paste may be replaced by a dry HF vapor etch process or the removal Step 6 may be skipped (i.e., removed) entirely for an all-dry front-end process. Further, the laser contact open step shown in Step 6 of Table 1 may be replaced by an etch paste process comprising etch paste deposition, dry, and rinse for a laser free front-end process.

Table 2 below shows a front-end process flow for the formation of a selective emitter solar cell having self aligned contacts using dopant paste and using separate contact open steps.

TABLE 2
Selective emitter solar cell having self aligned contacts
with dopant paste and separate contact open steps.

| | |
|---|---|
| 1 | Saw Damage Removal |
| 2 | APCVD Boron Doped Al2O3 + Undoped SiO2 |
| 3 | Laser ablation (ns UV and/or ps UV) |
| 4 | Dopant Paste (Phos Paste Print + Dry |
| 5 | Laser ablation (ns UV and/or ps UV) |
| 6 | Dopant Paste (Boron Paste Print + Dry) |
| 7 | Diffusion Anenal |
| 8 | Wet Etch HF Based/SKIP/HF Vapor |

Table 3 below shows a front-end process flow for the formation of a selective emitter solar cell having self aligned contacts with dopant paste and the application of a diffusion barrier.

TABLE 3
Selective emitter solar cell having self aligned contacts with
dopant paste and the application of a diffusion barrier.

| | |
|---|---|
| 1 | Saw Damage Removal |
| 2 | APCVD Boron Doped Al2O3 + Undoped SiO2 |
| 3 | Laser ablation (ns UV and/or ps UV) |
| 4 | Dopant Paste (Phos Paste Print + Dry + Boron Paste Print Dry) |
| 5 | APCVD USG dep |
| 6 | Diffusion Anneal |
| 7 | Wet Etch HF Based/SKIP/HF Vapor |

Alternatively, the diffusion barrier deposition shown in Step 5 of Table 3 as an APCVD USG deposition may also be an undoped paste print.

The process flow embodiments of Tables 2 and 3 may be used to reduce autodoping from dopant pastes during diffusion anneal.

Table 4 below shows a front-end process flow for the formation of a non abutted junction solar cell—such as that shown in FIG. 1C—having self aligned contacts with diffusion barrier dopant paste print. FIG. 1C is a cross-sectional diagram of a non-abutted junction solar cell with a self aligned contact structure having a dopant diffusion region with higher doping levels (e.g., greater than 1E18 cm-3) just below the metal to silicon absorber contact.

TABLE 4
Non abutted junction solar cell having self aligned
contacts with dopant paste print and non abutted
junction with diffusion barrier paste print.

| | |
|---|---|
| 1 | Saw Damage Removal |
| 2 | Undoped Paste Print + Dry |
| 3 | APCVD Boron Doped Al2O3 + Undoped SiO2 |
| 4 | Laser ablation (ns UV and/or ps UV) |
| 6 | Dopant Paste (Phos Paste Print − Dry + Boron Paste Print Dry) |
| 5 | Diffusion Anneal |
| 7 | Wet Etch HF Based/SKIP/HF Vapor |

Alternatively with reference to the non abutted junction solar cell flow of Table 4, Steps 2, 3, and, 4 of Table 4 may be replaced with two steps of APCVD boron doped silicon oxide (BSG1) deposition followed by picosecond (ps) CO2 laser—an alternative embodiment referred to as self aligned contacts with dopant paste print and non abutted junction with boron doped silicon oxide by APCVD.

Table 5 below shows the fabrication process flow for a non selective emitter solar cell having self aligned contacts and using phosphorous dopant paste.

TABLE 5
Non selective emitter solar cell having
self aligned contacts with dopant paste.

| | |
|---|---|
| 1 | Saw Damage Removal |
| 2 | APCVD Boron Doped Al2O3 + Undoped SiO2 |
| 3 | Laser ablation (ns UV and/or ps UV) |
| 4 | Dopant Paste (Phos Paste Print + Dry) |
| 5 | Diffusion Anneal |
| 6 | Wet Etch HF Based/SKIP/HF Vapor |
| 7 | Laser Abaltion (ps UV) |

Alternatively, Table 6 below shows the fabrication process flow for a non selective emitter solar cell having self aligned contacts and using phosphorus oxychloride POCl3 (POCl).

TABLE 6
Non selective emitter solar cell having self
aligned contacts with POCl based diffusion.

| | |
|---|---|
| 1 | Saw Damage Removal |
| 2 | APCVD Boron Doped Al2O3 + Undoped SiO2 |
| 3 | Laser ablation (ns UV and/or ps UV) |
| 4 | Diffusion Anneal |
| 5 | POCl Diffusion |
| 6 | Wet Etch HF Based/SKIP/HF Vapor |
| 7 | Laser Abaltion (ps UV) |

Table 7 below shows the fabrication process flow for a non selective emitter solar cell having self aligned passivated base contacts using dopant paste.

TABLE 7
Non selective emitter solar cell having self aligned
passivated base contacts with dopant paste.

| | |
|---|---|
| 1 | Saw Damage Removal |
| 2 | APCVD Boron Doped Al2O3 + Undoped SiO2 |
| 3 | Laser ablation (ns UV and/or ps UV) |
| 4 | Dopant Paste (Phos Paste Print + Dry) |
| 5 | Diffusion Anneal |
| 6 | Wet Etch HF Based/SKIP/HF Vapor |
| 7 | ALD Dep (Al2O3, TiO2, Al2O3 + TiO2) |
| 8 | Laser Abaltion (ps UV) |

Table 8 below shows the fabrication process flow for solar cells having self aligned base tunneling/hetero junction contacts—such as those shown in FIG. 1B.

TABLE 8
Solar cell having self aligned tunneling/hetero junction contacts.

| | |
|---|---|
| 1 | Saw Damage Removal |
| 2 | APCVD Boron Doped Al2O3 + Undoped SiO2 |
| 3 | Laser ablation (ns UV and/or ps UV) |
| 4 | Diffusion Anneal |
| 5 | Wet Etch HF Based/SKIP/HF Vapor |
| 6 | ALD Dep (Al2O3, TiO2, Al2O3 + TiO2) |
| 7 | Laser Abaltion (ps UV) |

Table 9 below shows the fabrication process flow for solar cells having self aligned contacts without a heavy diffusion region below the base contact.

TABLE 9
Solar cell having self aligned passivated base contacts.

| | |
|---|---|
| 1 | Saw Damage Removal |
| 2 | APCVD Boron Doped Al2O3 |
| 3 | Laser ablation (ns UV) Base Only |
| 4 | Wet Etch |
| 5 | Diffusion Anneal |
| 6 | Wet Etch (eg. Dilue HF, SC1 or dilute KOH based etc) |
| 7 | ALD Al2O3, TiO2 |
| 8 | Laser Ablation (ps UV) |

Alternatively, the self aligned contact structures and methods described herein may be applied to a

Table 10 below shows a front-end process flow for the formation of a solar cell having self aligned contacts with a field base—such as that shown in FIG. 1D. FIG. 1D is a cross-sectional diagram of a solar cell with field base and a self aligned contact structure having a dopant diffusion region with higher doping levels (e.g., greater than 1E18 cm-3) just below the metal to silicon absorber contact. Alternatively, for example, the HF Vapor Step 6 in Table 10 and which removes annealed dopant paste may be replaced with a wet etch step.

TABLE 10
Solar cell having a field base and self
aligned contacts with dopant paste.

| | |
|---|---|
| 1 | Saw Damage Removal |
| 2 | APCVD Undoped Al2O3 + Undoped SiO2 |
| 3 | Laser ablation (ns UV and/or ps UV) |
| 4 | Dopant Paste (Phos Paste Print − Dry + Boron Paste Print Dry) |
| 5 | Diffusion Anneal |
| 6 | HF Vapor |

Alternatively, Table 11 below shows a front-end process flow for the formation of a solar cell having a field base self aligned contacts with etch paste and dopant paste prints—such as that shown in FIG. 1D

TABLE 11
Solar cell having a field base and self aligned
contacts with etch paste and dopant paste print.

| | |
|---|---|
| 1 | Saw Damage Removal |
| 2 | APCVD Undoped Al2O3 + Undoped SiO2 |
| 3 | Etch Paste (Print, Cure, Rinse) |
| 4 | Dopant Paste (Phos Paste Print − Dry + Boron Paste Print Dry) |
| 5 | Diffusion Anneal |
| 6 | HF Vapor |

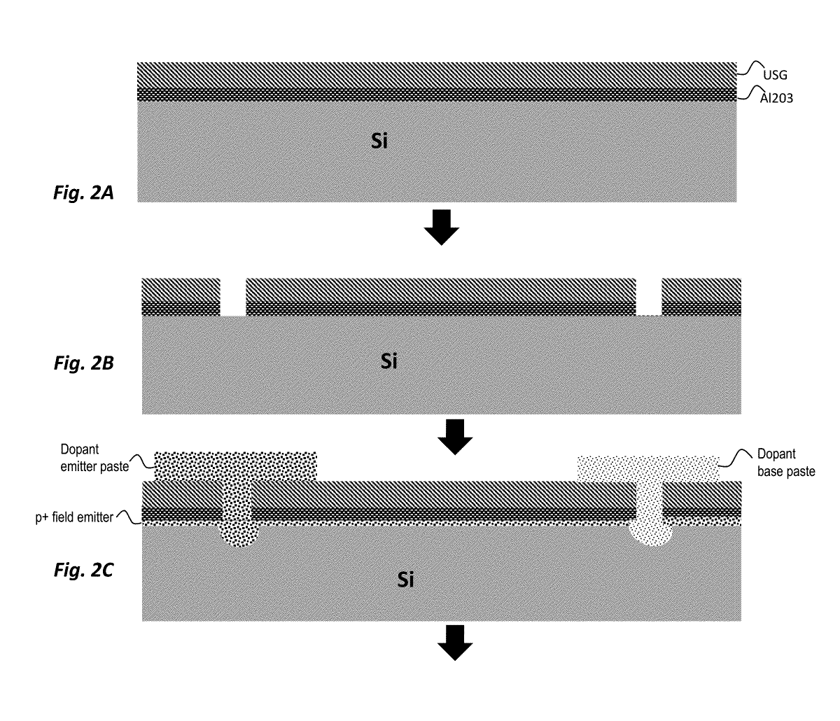

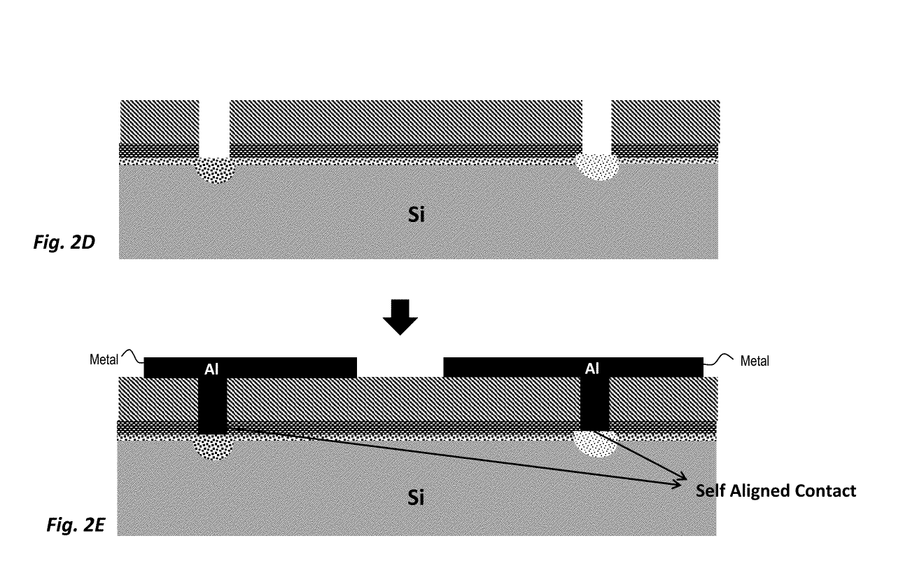

FIGS. 2A through 2E is a process flow representation showing cross-sectional diagrams of solar cells at various steps during the fabrication of a abutted junction interdigitated back contact solar cell having self aligned contacts with dopant paste. FIG. 2A shows an aluminum oxide (Al2O3) layer deposited (e.g., by APCVD) on a silicon substrate/wafer. The aluminum oxide layer may also have an undoped silicate glass layer. Next, as shown in FIG. 2B a nanosecond (ns or ps) laser opens base and emitter contacts. This step may also include a wet etch to remove any oxide residue (e.g., aluminum silicon oxide residue). Next, as shown in FIG. 2C dopant pastes are paste print in emitter and base regions followed by a diffusion anneal to drive-in/diffuse the dopants and form base and emitter regions. Next as shown in FIG. 2D dopant pastes are stripped (e.g., by wet etch). Next as shown in FIG. 2E metal is printed on the base and emitter regions and annealed resulting in minimal shunt risk.

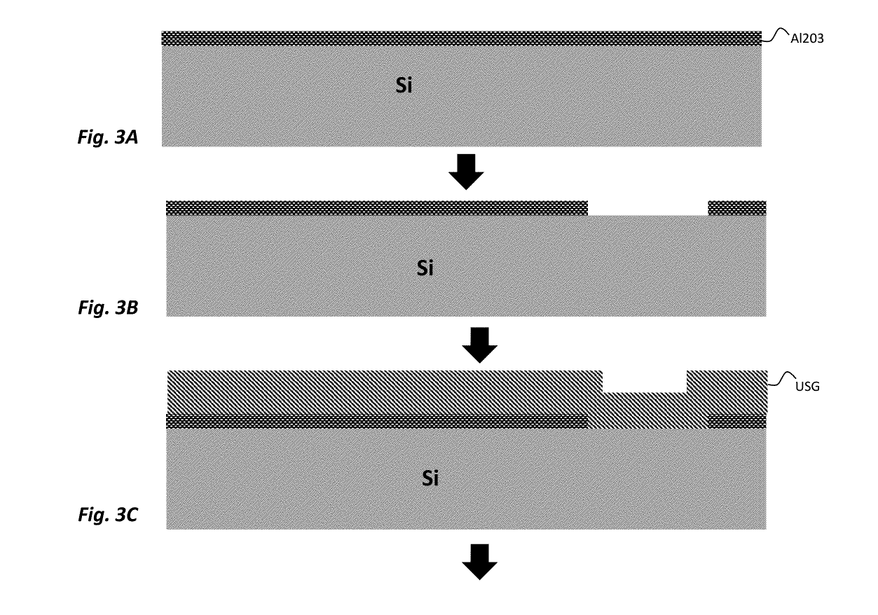

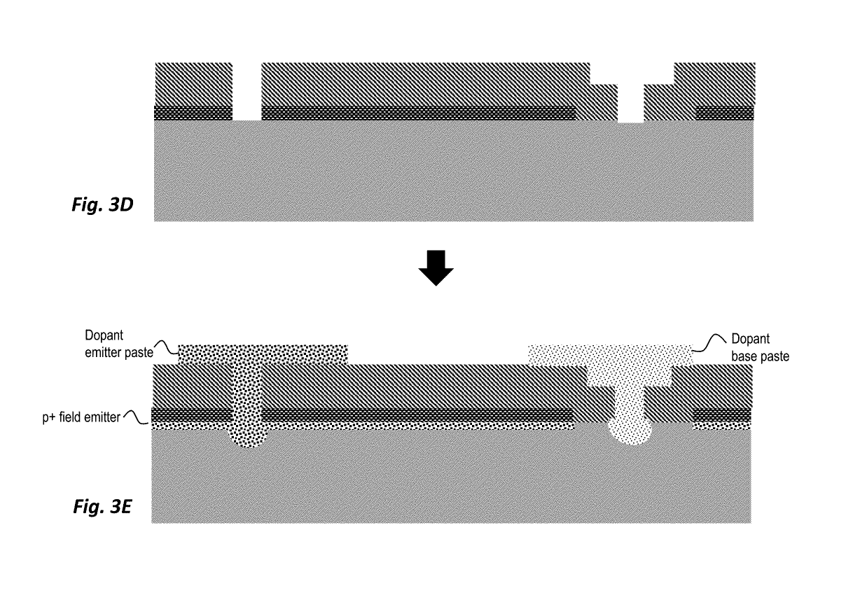

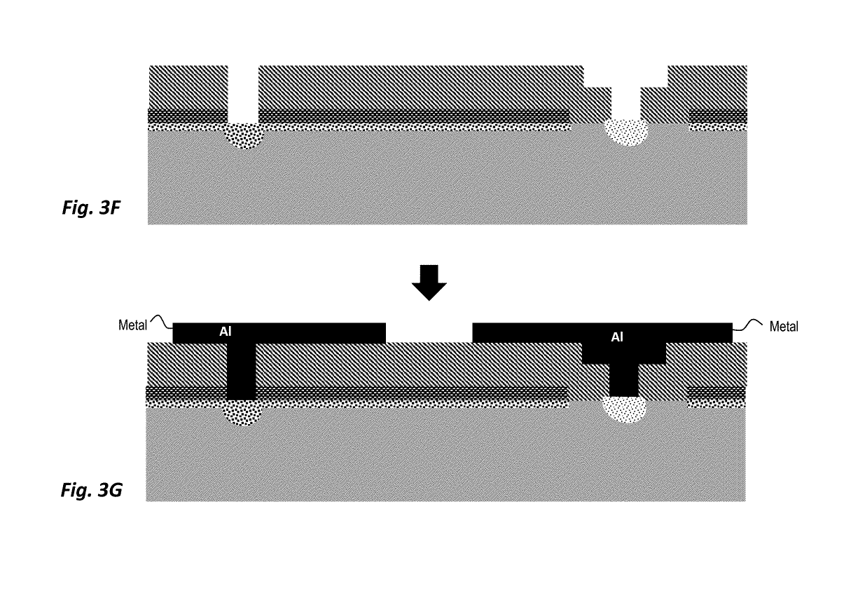

FIGS. 3A through 3G is a process flow representation showing cross-sectional diagrams of solar cells at various steps during the fabrication of a non abutted junction interdigitated back contact solar cell having self aligned contacts with dopant paste. FIG. 3A shows an aluminum oxide (Al2O3) layer deposited (e.g., by APCVD) on a silicon substrate/wafer. The aluminum oxide layer may also have an undoped silicate glass layer. Next, as shown in FIG. 3B a nanosecond (ns) laser opens base contacts. This step may also include a wet etch to remove any oxide residue (e.g., aluminum silicon oxide residue). Next, as shown in FIG. 3C a undoped silicate glass layer is deposited (e.g., by APCVD). Next as shown in FIG. 3D a pico second (ps) laser ablates base and emitter contact openings. Next, as shown in FIG. 3E dopant pastes are paste print in emitter and base regions followed by a diffusion anneal to drive-in/diffuse the dopants and form base and emitter regions. Next as shown in FIG. 3F dopant pastes are stripped (e.g., by wet etch). Next as shown in FIG. 3G metal is printed on the base and emitter regions and annealed resulting in minimal shunt risk.

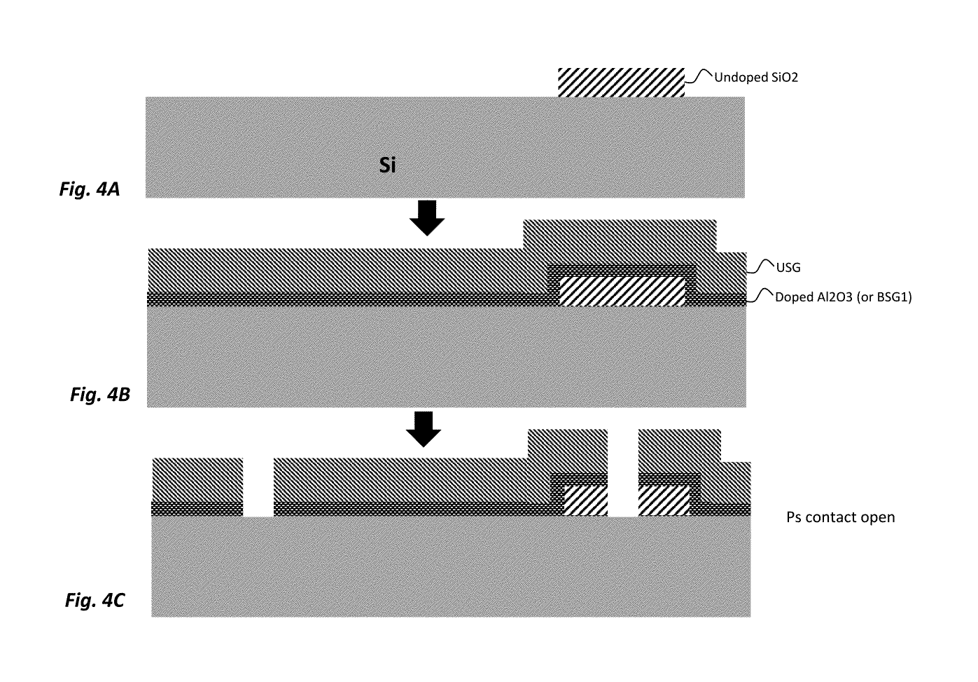

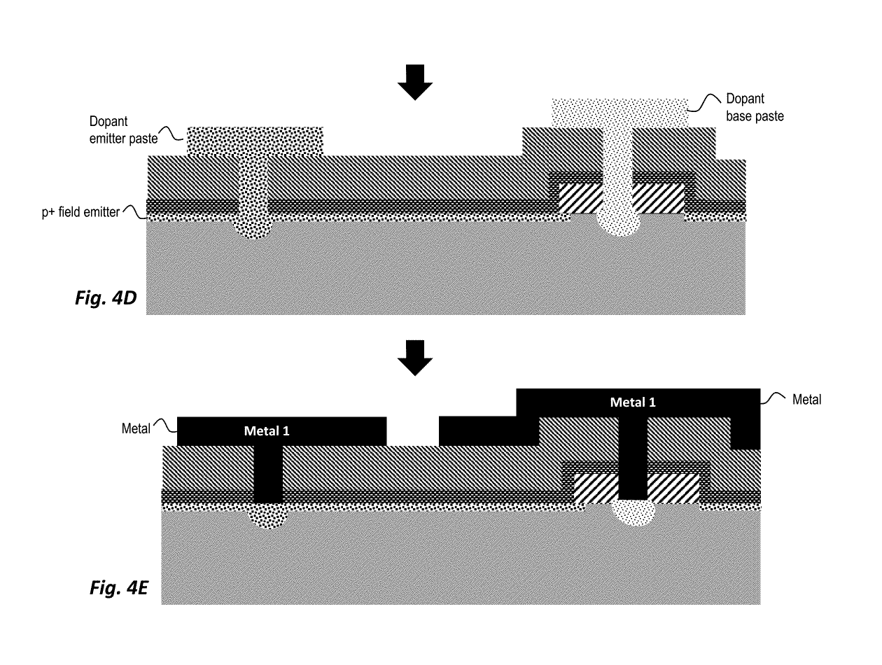

FIGS. 4A through 4E is a process flow representation showing cross-sectional diagrams of solar cells at various steps during the fabrication of a non abutted junction interdigitated back contact solar cell having self aligned contacts with dopant paste using an undoped paste first. FIG. 4A shows a undoped silicon oxide (SiO2) paste printed on the desired based regions of a silicon substrate/wafer only. Next, as shown in FIG. 4B a doped layer (e.g., doped aluminum oxide layer Al2O3 or doped borosilicate glass layer BSG1) and undoped silicate glass (USG) layer is deposited (e.g., by APCVD). The undoped silicate glass layer may have a thickness three to four times thicker as compared to the undoped layer. Next as shown in FIG. 4C a pico second (ps) laser ablates base and emitter contact openings. Next, as shown in FIG. 4D dopant pastes are paste print in emitter and base regions followed by a diffusion anneal to drive-in/diffuse the dopants and form base and emitter regions. Next dopant pastes are stripped (e.g., by wet etch). Next as shown in FIG. 4E metal is printed on the base and emitter regions and annealed resulting in minimal shunt risk.

While the methods to manufacture self-aligned back contact back junction solar cells are described in general context of CZ wafers, these methods are also equally applicable in context of epitaxially grown back contact back junction solar cells. In addition, the methods are applicable to both thick crystalline silicon (e.g., having an absorber thickness in the range of approximately 100 um to 200 um) as well as thin crystalline silicon back contact back junction solar cells (e.g., having an absorber thickness in the range of approximately 5 um to 100 um).

Generally and particularly applicable to the process flows represented in the tables below, emitter or base contacts are opened sequentially (in either order) or simultaneously using various field dielectric removal techniques such as using lasers or wet etch or etch paste. And subsequently, depositing the dopant source in the opened contact, driving the dopant into silicon at high temperature, and selectively removing/etching the dopant source while keeping the field dielectric unharmed from the etchant. This leaves the dopant driven into silicon only in the area under where the contact was opened leaving a self-aligned structure.

The methods of manufacturing described may be further categorized by the source of the under-contact dopants. These can be from a dopant paste (for example phosphorous for n-type and Boron for p-type) or deposited films which incorporate dopants in them, for example APCVD deposited Boron or phosphorous doped SiO2 films. Finally, a hybrid source where N+ and p+ dopant sources come from APCVD for one type and dopant paste for the other type of dopant. A further subcategory is defined by the technique to etch away/remove the dopant source which is applicable to both wafer and epitaxial based absorbers as well as dopant source categories (dopant paste, APCVC film, and hybrid dopant source). As an example, for oxide based dopant sources such as doped SiO2, either a wet process with HF can be used or a dry process using HF vapor phase etching may be deployed. If the field area is also SiO2 then the wet HF selectivity is obtained as a heavily doped SiOx film may etch much faster than an undoped film. Alternatively the field area stack may contain an Al2O3 (e.g., deposited using APCVD as well). This film, once treated at high temperatures for example greater than 900° C., may have high selectivity to HF solution. Alternatively, HF vapor also very selectively etch the dopant source.

Generally, if the contacts are opened simultaneously, then both dopant sources may be screen printed dopant paste. If the contacts are open sequentially, then a deposited film for both contacts or hybrid sources can be utilized.

Table 12 shows a front-end self aligned contact fabrication flow which yields a separated junction and is accomplished using dopant pastes (for example, screen printed dopant pastes). In the separated junction the emitter doping is not abutting the base contact doping and is separated by the background bulk doping of the base. Step 2 shows the deposition of the emitter followed by a cap. And although the emitter source is shown to be an APCVD deposited boron doped Al2O3, it may also be a boron doped SiO2 layer or another dopant source layer deposited using different means. The first laser ablation (Step 3) is to open up the separation between emitter and base doping such that upon anneal, there is a separation between the junctions. The flow suggests using laser ns UV and ps UV. Pico second green laser, a femto second laser, or etch paste or lithography techniques may also be used to create this base window. If pico second laser is used, it may be followed by a small wet etch of silicon to remove laser damage in silicon. Step 5 of Table 12 may also be done using pico second green laser or a femto second laser. Step 5 is a contact open within the base window for base contact as well as a contact open for the emitter. Both contacts are opened up in the same step—hence the method of printing the dopant source should be a selective print on top of these contacts such as screen printing of the dopant paste (as compared to a blanket deposition of a thin dopant sourced film). Subsequent to anneal to drive the dopants in both contacts in Step 7, the dopant source is either wet etched or etched selectively using HF vapor. In a separate embodiment if the source of the dopant is conductive as with silicon based dopant source, the etching step may be skipped (Step #8).

TABLE 12
Self aligned contact fabrication flow yielding
a separated junction using dopant pastes.

| | |
|---|---|
| 1 | Saw Damage Removal |
| 2 | APCVD Boron Doped Al2O3 + Undoped SiO2 |
| 3 | Laser ablation (ns UV and/or ps UV) |
| 4 | APCVD Undoped Oxide (Al2O3 or SiO2) |
| 5 | Laser ablation (ns UV and/or ps UV) |
| 6 | Dopant Paste (Phos Paste Print − Dry + Boron Paste Print Dry |
| 7 | Diffusion Anneal |
| 8 | Wet Etch HF Based/SKIP/HF Vapor |

In another embodiment, if there is risk of co-diffusion during drying or dopant driving the contacts can be opened sequentially. In this scenario, either base or emitter contact is opened first and the corresponding paste is printed and dried. Next, the other contact is opened and the corresponding paste is printed and dried. Finally, both pastes are driven in at the same time. This alternative may avoid cross contamination in the contact during drying and burn.

In a more extreme case if the problem of cross contamination is during the dopant drive, then contact open, dopant paste print, drying/burn, and anneal may be performed on one type of dopant. This sequence is followed by the same steps repeated for the second type of contact. This leads to two different anneals in which case the thermal budgets should be optimized.

In an abutted junction embodiment of the process flow in Table 12, Steps 3 and 4 may be skipped and contacts can be directly opened for both base and emitter.

Finally, in another variation, the field area may be capped by a thin film which is resistant to the dopant source etchant chemistry. In the case where the dopant source is SiOx based, and the etching chemistry is HF based, the cap layer may be APCVD based Al2O3 (undoped or doped) or titanium oxide (TiO2) or amorphous silicon (a-Si).

Table 13 shows a front end separated junction self aligned solar cell process flow using only APCVD deposited films which serves as dopant sources. This flow follows the same steps as Table 12 (with all the variations described above) until Step 4. At Step 5, only one type of contact is opened first. In this case it is the emitter contact (for an n-type back contact cell). This is followed by an APCVD BSG film which is the dopant source for emitter contact doping (Step 6). Next, the base contact is opened and PSG is deposited using APCVD. In a variation, the sequence of emitter and base contact open can be reversed. An abutted version of the separated junction flow described in Table 13 skips/removes Steps 3 and 4 to create abutted junctions.

TABLE 13
Self aligned contact fabrication flow yielding a separated
junction using APCVD doped dielectric films.

| | |
|---|---|
| 1 | Saw Damage Removal |
| 2 | APCVD Boron Doped Al2O3 with/out Undoped SiO2 |
| 3 | Laser ablation (ns UV and/or ps UV) |
| 4 | APCVD Undoped Al2O3 or Undoped SiO2 |
| 5 | ps Laser Contact Open |
| 6 | APCVD- Boron doped SiO2 |
| 7 | ps Laser Contact Open |
| 8 | APCVD - Phosphorous doped SiO2 |
| 9 | Diffusion anneal |
| 10 | Wet Etch HF Based/HF Vapor |

Table 14 below shows a front end separated junction self-aligned process flow using a hybrid approach. In this approach one of the dopant source is a deposited APCVD film while the other type of dopant source is a printed dopant paste.

TABLE 14
Self aligned contact fabrication flow yielding a
separated junction using a hybrid APCVD doped dielectric
film and phosphorous based dopant paste.

| | |
|---|---|
| 1 | Saw Damage Removal |
| 2 | APCVD Boron Doped Al2O3 with/out Undoped SiO2 |
| 3 | Laser ablation (ns UV and/or ps UV) |
| 4 | APCVD Undoped Al2O3 or Undoped SiO2 |
| 5 | ps Laser Contact Open |
| 6 | APCVD- Boron doped SiO2 |
| 7 | ps Laser Contact Open |
| 8 | Dopant Paste Print + Dry |
| 9 | Diffusion anneal |
| 10 | Wet Etch HF Based/HF Vapor |

The flow of Table 14 shares the first four steps (along with its variations) with Table 13. In Step 5 of Table 14, the emitter contact is opened. BSG is deposited in Step 6 and Step 7 opens base contact with a laser (note, although, the flow suggests using ps lasers, nano or femto second lasers with different wavelengths are not precluded as long as they meet the contact open requirements). Subsequently, phosphorous based dopant paste is printed, dried in Step 8. Step 9 is an anneal step to drive the dopants from the BSG and from the phosphorous paste to create under-contact doped areas, while step 10 removes the dopant sources based on either wet or HF vapor technique. An abutted version of the separated junction flow described in Table 14 skips/removes Steps 3 and 4 to create abutted junctions.

In a variation the flow of Table 14 the sequence of BSG2 (Step 6) and phosphorous dopant paste (Step 8) is reversed. Base contact is opened first, followed by phosphorous paste. This is in turn followed emitter contact and BSG2 deposition and the remaining flow is similar.

In another variation, the hybrid dopant sources are based on APCVD PSG and dopant paste boron such that the base contact is made with the APCVD deposited doped SiO2 film while the emitter contact is made using boron based dopant paste. This variation has further variations where the sequence of contact open and its accompanying dopant source has two possibilities.

Table 15 below is a front end process flow showing a variation of the hybrid approach of Table 14 where both dopant paste and doped dielectric films are used as a source of dopants for base and emitter under contact doping.

TABLE 15
Self aligned contact fabrication flow yielding a separated
junction using a hybrid APCVD doped dielectric film and phosphorous
based dopant paste with separated contact open by diffusion
anneal which takes out dopant co-diffusion risk

| | |
|---|---|
| 1 | Saw Damage Removal |
| 2 | APCVD Boron Doped Al2O3 with/out Undoped SiO2 |
| 3 | Laser ablation (ns UV and/or ps UV) |
| 4 | APCVD Un Doped Al2O3 and/or Undoped SiO2 |
| 5 | Laser ablation (ns UV and/or ps UV) |
| 6 | Dopant Paste (Phos Paste Print − Dry) |
| 7 | APCVD-Phos doped SiO2 |
| 8 | Diffusion Anneal |
| 9 | Laser ablation (ns UV and/or ps UV) |
| 10 | APCVD-Boron doped SiO2 |
| 11 | Diffusion Anneal |
| 12 | Wet Etch HF Based/SKIP/HF Vapor |

In a variation of Table 15 as compared to Table 14, both emitter and the base contacts are separated by APCVD-PSG and diffusion anneal. This is done to reduce the risk of dopant co-diffusion during diffusion anneal. Co-diffusion is a process when dopant source from base or emitter contact diffusion areas (phos or boron) from dopant paste (phos or boron) moves into other polarity (base or emitter) through gaseous phase. This process may avoided, for example, by putting a solid phase dopant sources (APCVD-PSG) on top of PSG and adding anneal before the next contact emitter contact open step—as shown in Table 15. In some cases, the paste is phosphorous and the base is opened first (for an n-type back contact cell) and in a variation the paste is the boron paste and the emitter is opened first.

A variation of the Table 15 process flow forms abutted junctions by skipping Steps 3 and 4 as shown in Table 16 below. As throughout this disclosure, the variations described in conjunction with Table 15 are equally applicable with the abutted junction flow.

TABLE 16
Self aligned contact fabrication flow yielding a abutted junction
using a hybrid APCVD doped dielectric film and phosphorous
based dopant paste with separated contact open by diffusion
anneal which takes out dopant co-diffusion risk.

| | |
|---|---|
| 1 | Saw Damage Removal |
| 2 | APCVD Boron Doped Al2O3 with/out Undoped SiO2 |
| 3 | Laser ablation (ns UV and/or ps UV) |
| 4 | Dopant Paste (Phos Paste Print − Dry) |
| 5 | APCVD-Phos doped SiO2 |
| 6 | Diffusion Anneal |
| 7 | Laser ablation (ns UV and/or ps UV) |
| 8 | APCVD-Boron doped SiO2 |
| 9 | Diffusion Anneal |
| 10 | Wet Etch HF Based/SKIP/HF Vapor |

In the variation of Table 15 and 16, the co-diffusion risk may be avoided by eliminating either APCVD-PSG or eliminating diffusion anneal.

Note, all the self-aligned process flows with their variations described so far are equally valid with an epitaxially grown thin film solar cell. A representative process flow which corresponds to the approach outlined in Table 12 (separated junction with dopant paste) is shown in Table 17 for an epitaxial thin film solar cell. Epitaxial flow may use the HF vapor approach to keep the flow mostly dry while the epitaxial absorber is still on the template. All the other embodiments with abutted and separate junctions with hybrid dopant sources or all APCVD dopant sources (shown for CZ wafers) are equally valid for epitaxial solar cells with the modified flow based on Table 16. The present application provides more detailed flows around other aspects of epitaxial formation. The self aligned attribute along with its manufacturing methods can be combined with any of the previously discussed variations of the epitaxial and CZ wafer based process flows.

TABLE 17
Self aligned contact fabrication flow yielding a separated junction
using dopant pastes based on an epitaxially formed substrate.

| | |
|---|---|
| 1 | Porous silicon on a thicker template |
| 2 | Epitaxial Thin Silicon growth on a template |
| 3 | APCVD Boron doped Al2O3 + undoped SiO2 |
| 4 | Laser Ablation (ns UV and or ps UV/green) |
| 5 | APCVD Undoped Oxide (Al2O3 or SiO2) |
| 6 | Laser Ablation base and emitter contact open (ns UV and or ps |
| | UV/green) |
| 7 | Dopant paste screen print (Phos paste print/dry + Boron paste |
| | print/dry) |
| 8 | Diffusion Anneal |
| 9 | HF Vapor Etch (can also be dry etch or wet etch which selectively |
| | removes dopant source) |
| 10 | Al Paste Print/dry |
| 11 | Anneal |
| 12 | Lamination using a backplane |
| 13 | Mechanical release of thin epi sbsorber (Template is separated from |
| | absorber and goes for a clean and next reuse) |
| 14 | icell cut |
| 15 | Texture and clean porous silicon layer |
| 16 | Front passivation and ARC (Example Al2O3 + SiN) |
| 17 | Via drill on the backplane |
| 18 | PVD |
| 19 | M2 Isolation |
| 20 | Anneal |

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

It is intended that all such additional systems, methods, features, and advantages that are included within this description be within the scope of the claims.

What is claimed is:

1. A back contact back junction thin solar cell, comprising:
a deposited semiconductor layer, comprising:
a light capturing frontside surface with a passivation layer,
a doped base region, and
a doped backside emitter region with a polarity opposite said doped base region;
a backside passivation dielectric layer and patterned reflective layer on said backside emitter region;
self aligned backside emitter contacts and backside base contacts connected to metal interconnects forming a first level interdigitated metallization pattern on the backside of said back contact back junction thin solar cell; and
at least one permanent support reinforcement positioned on the backside of said back contact back junction thin solar cell; and
a second metal layer which is separated from the first layer by said permanent backside support reinforcement structure, said second layer contacting to said first level metallization pattern locally through an interdigitated pattern of holes in said permanent backside support reinforcement structure.
